(19) United States
(12) Patent Application Publication
(10) Pub. No.: US 2010/0215853 A1
(43) Pub. Date: Aug. 26, 2010

(54) METHOD FOR CONTROLLING PROCESS GAS CONCENTRATION

(75) Inventors: Hans Ulrich Voeller, Blaubeuren (DE); Rolf Mueller, Schelklingen (DE); Robert Michael Hartung, Blaubeuren (DE)

Correspondence Address: HESLIN ROTHENBERG FARLEY & MESITI PC, 5 COLUMBIA CIRCLE, ALBANY, NY, 12203, US

(73) Assignee: CENTROTHERM THERMAL SOLUTIONS GMBH + CO. KG, Blaubeuren (DE)

(21) Appl. No.: 12/601,311

(22) PCT Filed: May 19, 2008
(86) PCT No.: PCT/EP08/56104

§ 371 Date: May 13, 2010

(30) Foreign Application Priority Data
May 23, 2007 (DE) 10 2007 024 266.4

(51) Int. Cl. C23C 16/52; C23C 16/448

(52) U.S. Cl. 427/248.1

(57) ABSTRACT

A method for controlling process gas concentration for treatment of substrates in a process space in which a medium is evaporated in a bubbler by bubbles of a carrier gas passed through the medium is achieved by producing a stipulated constant internal pressure in the bubbler and subsequent introduction of the carrier gas into the bubbler with simultaneous temperature control of the medium being evaporated within the bubbler to set a stipulated vapor pressure.

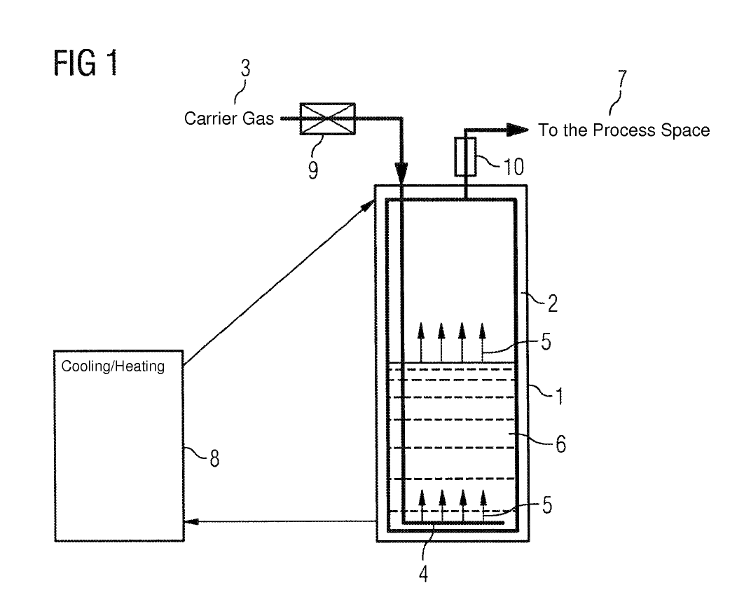

The invention concerns a method for controlling process gas concentration for treatment of substrates in a process space in which a liquid is evaporated in a bubbler by means of bubbles of a carrier gas passed through it.

So-called bubblers are used to generate vapor-like process gases, the bubblers consisting mainly of closed vessels into which the liquid being evaporated was introduced. The liquids being evaporated can be of any type, such as an acid with a stipulated concentration. Thus, the liquid could be formic acid (HCOOH) in different concentration. For the actual evaporation process a carrier gas is introduced to the lowermost region of the vessel via a nozzle bar with a number of openings. N2, N2H2, H2, etc., or also inert gases, for example, are considered as carrier gases. The carrier gas then rises in the bubbler bubble-like through the liquid and entrains parts of the liquid in vapor form. The carrier gas/vapor mixture so formed is then fed from the vessel to the process space.

In this process the bubbles take up the evaporated medium until a relative moisture content of 100% is reached. The concentration here depends on the pressure in the bubbler and the temperature, which can also lie at room temperature. Pressure regulation then occurs via a pressure reducer.

During treatment of substrates in a process space the maintenance of a stipulated concentration of a medium in a carrier gas can be of critical importance for the quality of the process. A shortcoming here is that during cooling of a gas mixture with a relative moisture content of 100% condensation cannot be prevented. As a result, the concentration of the medium in the carrier gas diminishes, which can simultaneously lead to undesired effects in the process.

The underlying task of the invention is now to devise a simple process for controlling the process gas concentration.

The task underlying the invention is solved in a method of the type just mentioned by creating a stipulated constant internal pressure in the bubbler and subsequent introduction of the carrier gas into the bubbler during simultaneous temperature control of the medium being evaporated within the bubbler to set a stipulated vapor pressure.

This process, which is surprisingly simple to implement, permits precise control of the concentration of the evaporated medium in the carrier gas.

In one embodiment of the invention the temperature in the bubbler is continuously varied to adjust the concentration of medium in the carrier gas to different process conditions without interrupting feed of the carrier gas into the bubbler.

In a continuation of the invention it is prescribed that the piping from the bubbler to the process space is included in temperature control, in which case the piping is preferably regulated at the same temperature as the bubbler.

The invention is further explained below in a practical example.

The corresponding drawing shows a schematic view of a bubbler for execution of the process according to the invention.

The bubbler 1 consists of a closable vessel surrounded with a cooling/heating jacket 2. To generate the evaporation process the bubbler 1 is connected to a feed 3 for carrier gas, which ends within bubbler 1 in the bottom area in a nozzle bar 4, which is provided with a number of nozzles to generate gas bubbles. The rising gas bubbles are schematically shown as arrows 5 in the figure. These gas bubbles rise through the liquid medium 6 introduced to the bubbler 1 and are then fed via piping 7 into a process space (not shown).

The cooling/heating jacket 2 is connected to a cooling/heating device 8 for temperature control of the liquid medium 6 in the bubbler 1.

A pressure reducer 9 for the carrier gas, with which the pressure in the bubbler 1 can be kept constant at a stipulated value, is also situated in the feed 3.

In the present practical example N2, N2H2, H2 are used as carrier gas. The invention can naturally also be accomplished with other carrier gases. Formic acid (HCOOH) is used here as liquid medium as reduction medium for oxide layers, for example, on surfaces to be soldered to each other.

Control of the concentration of the evaporated medium 6 in the carrier gas occurs by adjusting a stipulated/precalculated temperature by means of the cooling/heating device 8 at constant pressure in the bubbler. By changing the temperature in the bubbler 1 the vapor pressure of the medium can be continuously varied at constant pressure in the bubbler 1. The concentration of the evaporated medium in the carrier gas can therefore be controlled in particularly simple fashion over a broad range so that simple process optimization is also made possible during the treatment of substrates. The term substrate should be understood to also mean, for instance, objects or surfaces being soldered to each other.

In order to ensure that the concentration is not changed, the piping 7 can additionally be provided with pipe heating 10 at the feed point to the process space. This pipe heating 10 is connected to the cooling/heating device 8 so that the temperature of the piping can be set at the same temperature as in the bubbler 1.

The method according to the invention can be advantageously used for reflow soldering processes in a reflow soldering furnace (not shown) by introducing formic acid at a stipulated concentration into the process space. The formic acid serves here as reduction medium for oxide layers on the partners being soldered to each other.

### LIST OF REFERENCE NUMBERS

1 Bubbler
2 Cooling/heating jacket
3 Feed
4 Nozzle bar
5 Arrow
6 Liquid medium
7 Piping
8 Cooling/heating device
9 Pressure reducer
10 Pipe heating

1. Method for controlling process gas concentration for treatment of substrates in a process space, in which a medium is evaporated in a bubbler by bubbles of a carrier gas passed through the medium, comprising: creation of a stipulated constant internal pressure in the bubbler and subsequent introduction of the carrier gas into the bubbler with simultaneous temperature control of the medium being evaporated within the bubbler to set a stipulated vapor pressure.

2. Method according to claim 1, wherein temperature in the bubbler is variable to adjust concentration of the medium in the carrier gas to different process conditions without interrupting feed of carrier gas into the bubbler.

3. Method according to claim 1, wherein piping from the bubbler to the process space is included in the temperature control.

4. Method according to claim 3, wherein the piping is regulated at a same temperature as in the bubbler.
